(19) United States
(12) Patent Application Publication
(10) Pub. No.: US 2004/0120534 A1
(43) Pub. Date: Jun. 24, 2004

(54) Headphone automatic gain control system

(76) Inventor: William H. Mills JR., Sterling, VA (US)

Correspondence Address: LAW OFFICE OF LAWRENCE E LAUBSCHER, JR, 1160 SPA RD, SUITE 2B, ANNAPOLIS, MD, 21403, US

(21) Appl. No.: 10/323,258

(22) Filed: Dec. 19, 2002

(51) Int. Cl. H04R 1/10; H04R 3/00; H03G 3/00

(52) U.S. Cl. 381/96; 381/74; 381/121

(57) ABSTRACT

An automatic gain control circuit for use with a motorcycle radio and headset features an adjustable control for setting the maximum signal allowed to reach the headset, while allowing normal signal levels below that point to be controlled at the motorcycle radio. The circuit may be easily incorporated for use with a previously installed radio as well as an enhancement for new radio designs. Isolation transformers on both the input and output of the circuit eliminate the necessity to ground the circuit. Bass boost and internal gain circuits compensate for internal losses and headphone loading characteristics to provide near-transparent signal transfer below the set maximum signal level.

### BACKGROUND OF THE INVENTION

The present invention relates to the field of radio automatic gain control, and more specifically to automatic gain control of motorcycle radio signals received through a headphone.

Headphones offer many obvious advantages when used as radio receivers, particularly in a high-noise environment. A potential disadvantage of headphone use, however, results if a dangerously or painfully loud signal is emitted through the headphone and the user is unable to quickly or conveniently pull the headphone away from the ears or lower the signal level with a manual control.

Motorcycle officers commonly wear headphones that are connected to their police radios, but hands-free operation is particularly critical for a motorcycle officer because of the need to give full attention to the control of the motorcycle. Constant manual changing of the volume control in this environment is both distracting and dangerous, yet the potential problem of the user receiving an unacceptably loud signal is particularly high. It is likely, for example, that a police officer will set the volume level for “normal” operation relatively high to compensate for the noisy background level that accompanies the sounds of the motorcycle engine, sirens, and highway noise. While the volume level in radios found on police motorcycles is normally independent of the received radio frequency signal level, is it highly dependent on the talker voice level. Officers who set their listening level for “normal” may have a need to adjust the volume control to protect their ears from excessively loud talkers.

Excessively loud talking levels are likely if the talker is excited or feels he must speak loudly to overcome local ambient noise. As a result, a listening officer may be placed in a hazardous situation while the vehicle is in motion if he is required to manually move his hands from the handlebars to manually adjust the radio volume. The problem is compounded if either the high volume level or the fact that he has reduced the volume reduces his ability to hear a subsequent speaker talking at or below a more “normal” volume level.

### BRIEF DESCRIPTION OF THE PRIOR ART

Headset control circuits are known that attempt to control peak volume level in various ways. For example, high volume signals may be eliminated by circuits that suppress any signal voltage above a predetermined level. Disadvantages of such circuits include the fact that they are not readily adjustable for use in different environmental conditions, and also that they commonly introduce unpleasant distortions into the received signal.

Alternative devices for noise suppression generally are also capable of attenuating the peak volume level of a received signal. U.S. Pat. No. 6,118,878 to Jones describes an active noise cancellation system employing a complex arrangement of mechanical and electrical devices including microphones and sound generators. The additional cost, complexity, and power requirements of such systems are not readily compatible with the environment in which police motorcycles operate.

Automatic gain control (AGC) circuits are also known for limiting the maximum volume level of a received signal. U.S. Pat. No. 5,369,711 to Williamson, III, describes an AGC circuit for limiting the peak volume level in a headset by controlling the signal across a capacitor. The principal disadvantages of this approach for the application identified above are complexity of the feed-forward control circuit used and difficulties in setting of the “nominal” output level within the AGC device.

It is desired to have an automatic gain control circuit that efficiently limits the maximum volume level in a headphone while drawing very little power. The automatic gain control circuit can be added to or detached from existing headset circuits without modification to the existing cable harness. Ideally, the automatic gain control circuit will control only the maximum level of the signal reaching the headphone, with the nominal signal controlled at the signal source.

### SUMMARY OF THE INVENTION

The present invention is a headphone automatic gain control circuit intended primarily as an accessory attachment to radio systems currently installed on police motorcycles. It overcomes deficiencies in prior art devices with a much-simplified analog feedback circuit, with proper attack and decay time achieved by inherent low pass filter and hysteresis characteristics of a photosensitive resistor-based optical isolator. The present invention allows setting peak acceptable sound level presented to a headset, without restricting control of nominal level. “Nominal” gain control remains at the radio receiver, where it can be adjusted to compensate for varying background noise levels to which a police motorcycle is subjected in normal operation. Bass boost and internal gain compensate for internal losses and headphone loading characteristics to provide near-transparent signal transfer below a set maximum signal level. Variable gain control minimizes signal distortion over prior art “clipping” techniques. A gain control loop reacts quickly to excessive signal levels to reduce the signal to the headphones, then recovers within approximately the same time as the radio squelch circuit, so that the level for the next talker is unaffected by the reaction to an overly loud talker.

Accordingly, it is an object of the present invention to provide gain control that is not dependent on the real time output voltage of the feedback amplifier.

It is also an object to provide a gain control circuit that is immune from feedback bias such as is generated by field effect transistors (FETs).

It is another object to provide a gain control circuit utilizing an optical feedback device.

Is another object to provide a gain control circuit employing only a single adjustable gain amplifier stage.

It is still another object to provide a gain control circuit that utilizes variable gain rather than “clipping” to minimize signal distortion.

It is a further object to reduce the number of required parts, potentially reducing device cost and power drain.

An automatic gain control circuit having these and other advantages includes a first inverting variable gain amplifier having an input for receiving audio signals of varying levels and an output. A second inverting variable gain amplifier has an input connected to the output of the first amplifier and an output, and a light emitting diode has an input connected to the output of the second amplifier, the diode providing an optical signal in response to a control signal. A photosensitive resistor responds to the optical signal and has an output connected to the input of the first amplifier, the first amplifier being responsive to the output of the photosensitive resistor to vary the gain of the first amplifier. A variable gain feedback circuit is connected between the output of the first amplifier and the input of the diode. The feedback circuit is adjustable to limit only the maximum level of the signal at the output of the first amplifier by controlling the optical signal from the diode. Normal signal levels below that point are unaffected by the feedback circuit, which permits them to be controlled at the motorcycle radio.

A motorcycle communications system employing the invention includes a radio, a headset, and an automatic gain control circuit. The gain control circuit includes a first inverting variable gain amplifier having an input connected to the radio for receiving audio signals of varying levels from the radio and an output connected to the headset for providing signals to the headset. A second inverting variable gain amplifier has an output and an input connected to the output of the first amplifier. A light emitting diode has an input connected to the output of the second amplifier, the diode providing an optical signal in response to a control signal. A photosensitive resistor responds to the optical signal and has an output connected to the input of the first amplifier, which responds to the output of the photosensitive resistor to vary the gain of the first amplifier. A variable gain feedback circuit connects the output of the first amplifier to the input of the diode and is adjustable to limit the maximum level of the signal at the output of the first amplifier by controlling the optical signal from the diode, while allowing normal signal levels below that point to be controlled at the motorcycle radio.

### BRIEF DESCRIPTION OF THE DRAWINGS

Other objects and advantages of the invention will become apparent from a study of the following specification when viewed in light of the accompanying drawing, in which:

FIG. 1 is a block diagram of one embodiment of the invention;

FIG. 2 is a block diagram of a power supply circuit for use with the embodiment of FIG. 1;

FIG. 3 is a more detailed circuit diagram of the embodiment of FIG. 1;

FIG. 4 is a circuit diagram of the power supply circuit of FIG. 2;

FIG. 5 is a plot illustrating the peak signal transfer characteristic of the embodiment of FIG. 1; and

FIG. 6 illustrates the embodiment of FIG. 1 packaged as an accessory for use with existing motorcycle radios.

### DESCRIPTION OF THE PREFERRED EMBODIMENT

FIG. 1 illustrates a circuit 20, in which an isolation transformer 24 receives a signal from an input 22 and provides a signal to an input loss compensation circuit 26. A compression stage circuit 28 receives a signal from the input loss compensation circuit 26. The compression stage circuit includes a variable amplifier 30 and a photo-electronic gain control circuit 32. A signal from the compression stage circuit 28 is provided to an output loss pre-compensation circuit 34 and to a compression point adjustment circuit 36. The compression point adjustment circuit 36 provides a signal to the photo-electronic gain control circuit 32, which, in turn, provides gain control to amplifier 30. An output transformer 38 receives a signal from the output loss pre-compensation circuit 34 and provides a signal to an output 40.

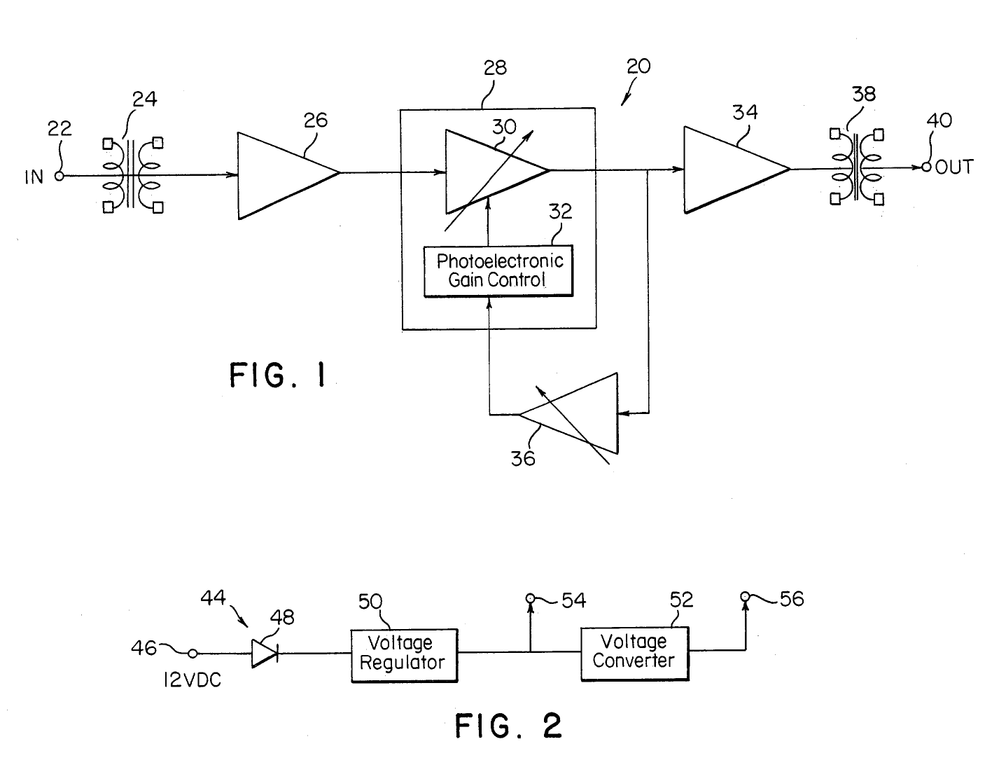

FIG. 2 illustrates a power supply circuit 44 for use with the circuit 20 of FIG. 1. A battery voltage input 46 is connected to a diode 48. A positive voltage regulator 50 converts the switched battery voltage, which would normally be +12 volts, to a voltage suitable for operating circuit 20. An output 54 permits connection of the regulated positive voltage to circuit 20. A negative voltage converter 52 receives the signal from the positive voltage regulator 50 and provides a negative voltage as needed to output 56 for operation of circuit 20. The diode 48 connected between input 46 and positive voltage regulator 50 provides reverse polarity protection for the circuit 44.

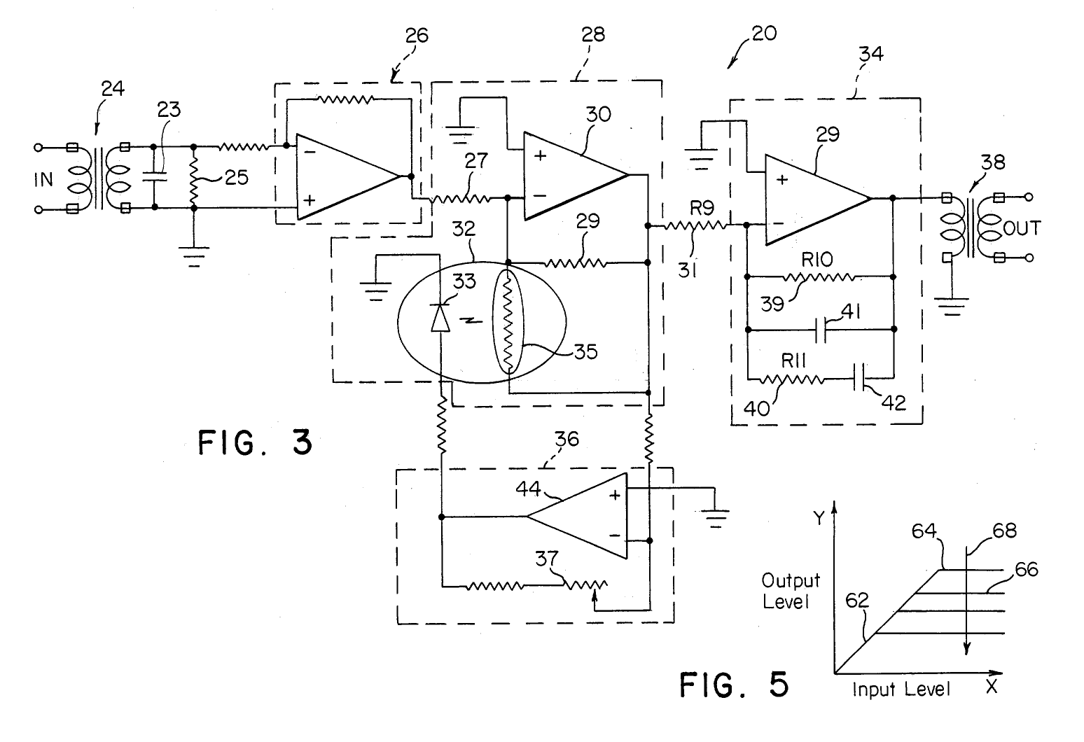

Referring now to FIG. 3, the isolation transformer 24 may be a 300/600 ohm audio transformer such as the model 42TL023 audio transformer distributed by Mouser Electronics. Output transformer 38 may be a 500/16 ohm audio transformer such as the Mouser Electronics model 42TL026 audio transformer. The function of the transformers is to prevent grounding of either side of the headset circuit, which is an important safety consideration for a vehicle-mounted radio. The input loss compensation circuit 26, output loss pre-compensation circuit 34, and compression point adjustment circuit 36 may all be implemented with inverting operational amplifiers. A single quad JFET-input general purpose operational amplifier module such as Mouser Electronics model TL084IN may be used to supply all of the operational amplifiers required for circuit 20. The function and design of input loss compensation circuit 26 is well known in the prior art and is not further described here. Bass boost and internal gain provided by circuits 26 and 34 compensate for internal losses and headphone loading characteristics to provide near-transparent signal transfer below the set maximum signal level. Input losses result from normal internal loss of the isolation transformer 24, from use of a termination resistor (not shown) to reflect near-normal headphone impedance back to the radio output, and a high frequency noise shunting capacitor 23 across the input load resistor 25. Almost all of the loss, however, results from the isolation transformer 24.

The circuit 34 pre-compensates for coupling loss in the output transformer 38. The negative input of an amplifier 29 is connected to the output of the amplifier 30 through a resistor 31 having a value R9. The negative input of a resistor 39, having a value R10, resistor 40, having a value R11, and capacitor 42 produce a bass-boost “shelving filter.” At DC (direct current), capacitor 42 opens that path including resistor 40, so gain is set by the ratio R10/R9. As the frequency increases, the impedance of capacitor 42 drops, and that impedance plus R11 starts to shunt resistor 39, reducing the gain. Past the 3 dB point of capacitor 42 and resistor 40, the gain quickly approaches [(R10*R11)/(R10+R11)/R9. Preferably, this “shelf” will be set for about 6 dB less gain at 1000 Hz than at 300 Hz. Capacitor 41 introduces a high frequency roll-off. Preferably, the 3 dB point will be set for about 10 kHz, which will eliminate high frequency noise resulting from excessive AGC bandwidth. Also, this helps reduce the 20 kHz whistle from the negative voltage converter, which may be audible to operators having particularly sensitive hearing.

Compression stage circuit 28 and compression point adjustment circuit 36 constitute an optical feedback loop that provides gain control. The negative input of amplifier 30 is connected to the output of amplifier 26 through a resistor 27. A photosensitive resistor 35 is connected in parallel with a feedback resistor 29 of amplifier 30. Photosensitive resistor 35 is illuminated by a light emitting diode (LED) 33, the intensity of which is determined by the current flowing through it. The varying resistance of photosensitive resistor 35 varies the gain of amplifier 30. A manually controllable variable resistor 37, connected as a negative feedback resistor across the operational amplifier 36, provides the compression point (maximum volume) adjustment by controlling the current flow through the LED 33. The photosensitive resistor 35 acts as a variable resistor as current flow through the LED 33 varies, thereby providing the negative feedback resistance to effect gain control via operational amplifier 30.

The input resistor 27 and feedback resistor 29 of amplifier 30 are selected for a desired nominal amplifier gain. The photosensitive resistor 35 is selected for a “dark” resistance value that is much greater than that of feedback resistor 29 of amplifier 30. The photosensitive resistor 35 is also selected for an “illuminated” resistance that is much less than that of feedback resistor 29 of amplifier 30. As a result, the gain of the operational amplifier 30 is unaffected until the feedback level, i.e., the output of operational amplifier 44, causes LED 33 to sufficiently illuminate photosensitive resistor 35. At that point, the gain of operational amplifier 30 is forced well below unity. Accordingly, by setting the gain of operational amplifier 44, the feedback loop provides sharp output limiting.

Photosensitive resistor 35 will have a response time to a rising signal level that is selected to provide sufficiently rapid response to minimize the amount of excess signal power reaching the headset without producing significant signal distortion. A response time of about 2-5 milliseconds has been found to work well in operational tests. The response time of photosensitive resistor 35 to a falling signal level is selected to provide gain recovery to the nominal level more slowly than a normal word-to-word time interval, but before the next transmission would normally be received. That is, the reaction time should be sufficiently long to avoid causing noticeable fluctuations in the speech signal passed to the headphone, while sufficiently short to allow recovery of operational amplifier 30 to nominal gain before a signal from the next speaker is received. A response time of about 500 milliseconds has been found to work well in operational tests.

A combination of the light emitting diode 33 and the photosensitive resistor 35 suitable for use in this embodiment is available from SILONEX Corporation as Optocoupler Model NSL-32.

The single adjustable gain amplifier stage of circuit 20 responds to root-mean-square (RMS) signal levels and is inherently a low pass device. As a result, the attack and decay characteristics of the photosensitive resistor provide response and recovery characteristics similar to that of the squelch circuit of the supported radio, without the requirement for separate timing elements as is found in many prior art devices. As a result, the volume level for a next, quieter, talker is unaffected by the reaction to an overly loud talker.

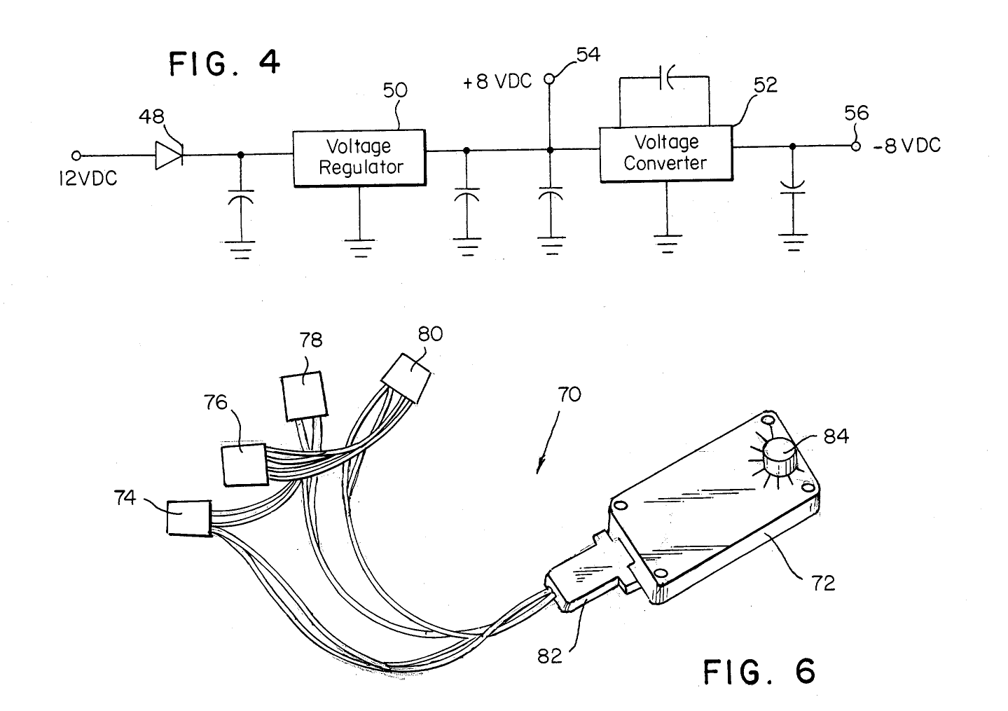

The power supply circuit illustrated in FIG. 4 includes a voltage regulator 50 that can be implemented with a 3-terminal positive voltage regulator circuit such as is manufactured as model 7808 by U.S. Microwaves Corporation. In a preferred embodiment, voltage regulator 50 reduces the +12 volt battery voltage to +8 volts to drive the operational amplifiers in circuit 20. Voltage converter 52 converts the +8 volts from voltage regulator 50 to −8 volts, which is also needed to drive the operational amplifiers in circuit 20. Voltage converter 52 may be implemented with an Intersil Corporation model ICL7660S voltage converter.

FIG. 5 illustrates a representative peak signal transfer characteristic of the circuit of FIG. 1, with the x-axis representing the maximum input signal level (volume) provided at terminal 22 and the y-axis representing the maximum output level provided at terminal 40. As control loop gain is increased, the input signal level at which gain compression occurs is pushed lower. The curve illustrates the relationship between maximum input level and maximum output level as control loop gain is increased. As shown by line segment 62, that relationship is linear until the compression point is reached. Past the compression point, higher maximum levels force a near real-time reduction in gain, restraining the maximum output signal level to the preset value. While line segments 66 and 68 are illustrated as perfectly flat, it will be readily understood by those skilled in the art that an exactly correct curve will be only close to flat. This results from the fact that increasingly higher maximum input levels do push maximum outputs slightly higher. Also, the loop delay required to minimize signal distortion allows sharply increasing signals to exceed the set limit for a few milliseconds before gain is suppressed. It is believed that this is more desirable than the signal distortion that would result from a more rapid loop response. The curve defined by line segments 62 and 64 describes the input/output relationship when rheostat 37 is set for minimum loop gain. As rheostat 37 is adjusted to increase the loop gain, the maximum output level decreases, as represented by arrow 68, to a point where the input/output relationship is defined by line segments 62 and 66. Adjustment of rheostat 37 to further increase the loop gain will continue to drop the maximum output level as illustrated.

The embodiment of FIG. 1 may be incorporated into a radio design or it may be implemented as an accessory for use with existing motorcycle radios. FIG. 6 illustrates an embodiment of the invention packaged as an accessory 70 for existing motorcycle radios. A weatherized, shock and vibration resistant box 72 contains the electronic circuits described above, which are accessed through a multi-pin connector 82. A rheostat having a knob 84 permits manual adjustment of variable resistor 37. Alternatively, knob 84 may be replaced with a screwdriver-adjusted locking control as is well known in the prior art. Four connectors 74, 76, 78 and 80 are provided for connecting the invention into the wiring harness of the existing motorcycle electrical and radio systems. In particular, a first connector 74 will route the headset connection (SPKR HI and SPKR LO, the two sides of a balanced input signal) through circuit 20 while providing a normal-through for the microphone connections. A second connector 78 delivers the output of circuit 20 to the radio headset input. Connectors 76 and 80 provide power to circuit 20 and the emergency plug that is a conventional part of most prior art police motorcycle radios. Preferably a switched battery source will be tapped by connector 76 so that circuit 20 will be powered only when the radio is on.

Adjustment of the maximum volume level of the circuit is made by the operator when the system is installed. It would not normally be necessary to adjust the circuit again by that operator. To perform the initial adjustment, the single control 84 is used to set the maximum acceptable signal level to the headphone. Using control 84, the operator initially adjusts rheostat 37 to minimum rotary loop gain. While wearing the headphone, the operator sets the radio volume control at a point that is “too loud,” and then adjusts rheostat 37 until an acceptable signal level is obtained. The radio volume control is then returned to what the operator considers to be a normal listening level and the radio is ready for use.

While the preferred forms and embodiments of the invention have been illustrated and described, it will be apparent to those of ordinary skill in the art that various changes and modification may be made without deviating from the inventive concepts set forth above.

What is claimed is:

1. An automatic gain control circuit, comprising:
(a) a first inverting variable gain amplifier having an input for receiving audio signals of varying levels and an output;
(b) a second inverting variable gain amplifier having an output and an input connected to the output of the first amplifier;
(c) a light emitting diode that provides an optical signal in response to a control signal;
(d) a photosensitive resistor responsive to the optical signal and having an output connected to the input of the first amplifier, the first amplifier being responsive to the photosensitive resistor to vary the gain of the first amplifier; and
(e) a variable gain feedback circuit connecting the output of the first amplifier to the input of the diode, the feedback circuit being adjustable to limit only the maximum level of the signal at the output of the first amplifier by controlling the optical signal from the diode while not otherwise affecting the nominal level of the output signal of the first amplifier.

2. The automatic gain control circuit of claim 1, and further comprising a fixed negative feedback resistor connected in parallel with the photosensitive resistor and the first amplifier.

3. The automatic gain control circuit of claim 2, wherein the photosensitive resistor has a “dark” resistance value matched to the value of the fixed negative feedback resistor, wherein the gain of the first amplifier remains relatively constant until the output of the first amplifier reaches a predetermined threshold level

4. The automatic gain control circuit of claim 3, wherein the photosensitive resistor has an “illuminated” resistance value matched to the value of the fixed negative feedback resistor, wherein the gain of the first amplifier is controlled by the output of the feedback circuit only after the threshold level is reached.

5. The automatic gain control circuit of claim 4, wherein the photosensitive resistor has an increasing signal response time that is about 2 to 5 milliseconds.

6. The automatic gain control circuit of claim 5, wherein the photosensitive resistor has a decreasing signal response time that is about 500 milliseconds.

7. The automatic gain control circuit of claim 4, wherein the photosensitive resistor has an increasing signal response time that is selected to minimize the amount of excess signal power that reaches the first amplifier output.

8. The automatic gain control circuit of claim 7, wherein the photosensitive resistor has a decreasing signal response time that is selected to minimize signal fluctuations at the output of the first amplifier.

9. The automatic gain control circuit of claim 1, wherein the variable gain feedback circuit further comprises:
(a) a second inverting variable gain amplifier having an input connected to the output of the first amplifier and an output connected to the diode; and
(b) a variable resistor connected in parallel with the second amplifier, the variable resistor being adjustable to control the maximum level of the output of the first amplifier.

10. The automatic gain control circuit of claim 9, and further comprising an isolation transformer connected to the input of said first amplifier.

11. The automatic gain control circuit of claim 10, and further comprising a third amplifier connected between the isolation transformer and the first amplifier to compensate for losses introduced by the isolation transformer.

12. The automatic gain control circuit of claim 11, and further comprising an audio transformer connected to the output of the first amplifier.

13. The automatic gain control circuit of claim 12, and further comprising a fourth amplifier connected between said first amplifier and said audio transformer to compensate for losses introduced by the audio transformer.

14. The automatic gain control circuit of claim 13, and further including means for increasing the bass response of the output of the first amplifier.

15. A motorcycle communication system, comprising:
(a) a radio;
(b) a headset; and
(c) an automatic gain control circuit, comprising:
(1) a first inverting variable gain amplifier having an input connected to the radio for receiving audio signals of varying levels from the radio and an output connected to the headset for providing signals to the headset;
(2) a second inverting variable gain amplifier having an output and an input connected to the output of the first amplifier;
(3) a light emitting diode having an input connected to the output of the second amplifier, the diode providing an optical signal in response to a control signal;
(4) a photosensitive resistor responsive to the optical signal and having an output connected to the input of the first amplifier, the first amplifier being responsive to the photosensitive resistor to vary the gain of the first amplifier; and
(5) a variable gain feedback circuit connecting the output of the first amplifier to the input of the diode, the feedback circuit being adjustable to limit the maximum level of the signal at the output of the first amplifier by controlling the optical signal from the diode while allowing the nominal level of the output signal of the first amplifier to be controlled at the signal source.

16. The motorcycle communication system of claim 15, wherein the automatic gain control circuit is detachably connected to the radio and the headset.

17. An automatic gain controlled radio, comprising:
(a) an audio signal source;
(b) a first inverting variable gain amplifier having an input for receiving audio signals of varying levels from the source and an output;
(c) a second inverting variable gain amplifier having an output and an input connected to the output of the first amplifier;
(d) a light emitting diode that provides an optical signal in response to a control signal;
(e) a photosensitive resistor responsive to the optical signal and having an output connected to the input of the first amplifier, the first amplifier being responsive to the photosensitive resistor to vary the gain of the first amplifier; and
(f) a variable gain feedback circuit connecting the output of the first amplifier to the input of the diode, the feedback circuit being adjustable to limit the maximum level of the signal at the output of the first amplifier by controlling the optical signal from the diode while allowing the nominal level of the output signal of the first amplifier to be controlled at the audio signal source.

18. The automatic gain control circuit of claim 17, and further comprising a fixed negative feedback resistor connected in parallel with the photosensitive resistor and the first amplifier.

19. The automatic gain control circuit of claim 18, wherein the photosensitive resistor has a “dark” resistance value matched to the value of the fixed negative feedback resistor, wherein the gain of the first amplifier remains relatively constant until the output of the first amplifier reaches a predetermined threshold level

20. The automatic gain control circuit of claim 19, wherein the photosensitive resistor has an “illuminated” resistance value matched to the value of the fixed negative feedback resistor, wherein the gain of the first amplifier is controlled by the output of the feedback circuit only after the threshold level is reached.

21. The automatic gain control circuit of claim 20, wherein the photosensitive resistor has an increasing signal response time that is about 2 to 5 milliseconds.

22. The automatic gain control circuit of claim 21, wherein the photosensitive resistor has a decreasing signal response time that is about 500 milliseconds.

23. The automatic gain control circuit of claim 20, wherein the photosensitive resistor has an increasing signal response time that is selected to minimize the amount of excess signal power that reaches the first amplifier output.

24. The automatic gain control circuit of claim 23, wherein the photosensitive resistor has a decreasing signal response time that is selected to minimize signal fluctuations at the output of the first amplifier.

25. The automatic gain control circuit of claim 17, wherein the variable gain feedback circuit further comprises:
(a) a second inverting variable gain amplifier having an input connected to the output of the first amplifier and an output connected to the diode; and
(b) a variable resistor connected in parallel with the second amplifier, the variable resistor being adjustable to control the maximum level of the output of the first amplifier.

26. The automatic gain control circuit of claim 25, and further comprising an isolation transformer connected to the input of said first amplifier.

27. The automatic gain control circuit of claim 26, and further comprising a third amplifier connected between the isolation transformer and the first amplifier to compensate for losses introduced by the isolation transformer.

28. The automatic gain control circuit of claim 27, and further comprising an audio transformer connected to the output of the first amplifier.

29. The automatic gain control circuit of claim 28, and further comprising a fourth amplifier connected between said first amplifier and said audio transformer to compensate for losses introduced by the audio transformer.

30. The automatic gain control circuit of claim 29, and further including means for increasing the bass response of the output of the first amplifier.
